(19) United States
(12) Patent Application Publication
(10) Pub. No.: US 2026/0250841 A1
(43) Pub. Date: Aug. 27, 2026

(54) MULTI-CHAMBERED CHEMICAL SOLID PRECURSOR AMPOULE

(71) Applicant: Versum Materials US, LLC, Tempe, AZ (US)

(72) Inventors: Charles M. Birtcher, Valley Center, CA (US); Robert Eschbach, Oceanside, CA (US)

(21) Appl. No.: 19/163,606

(22) PCT Filed: Mar. 4, 2024
(86) PCT No.: PCT/US24/18320

§ 371 Date: Sep. 9, 2025

Related U.S. Application Data
(60) Provisional application No. 63/489,290, filed on Mar. 9, 2023.

(51) Int. Cl. C23C 16/448

(52) U.S. Cl. CPC C23C 16/4481

(57) ABSTRACT

A multi-chamber ampoule having a multi-chamber container and a lid is disclosed. The lid includes conduits for fluidly connecting multiple chambers of the container. The sublimation rate of each chamber is defined by a surface area of each chamber, a temperature of each chamber, and a headspace pressure of each chamber, and the sublimation rate of each chamber is substantially equal.

### CROSS-REFERENCE TO RELATED APPLICATIONS

This application claims the benefit of U.S. Provisional Patent Application having Ser. No. 63/489,290 filed on Mar. 9, 2023.

### BACKGROUND

The present disclosure relates generally to precursor ampoules, and more particularly to multi-chambered solid precursor ampoules.

Solid-phase precursors to deliver precursor vapor for vapor-utilizing applications such as semiconductor manufacturing and fabrication. A carrier gas is supplied to an ampoule containing solid precursor in which the solid precursor vaporizes to produce precursor vapor through a sublimation process. To ensure consistent delivery of precursor vapor, the atmospheric conditions inside the ampoule, as well as the head space pressure and temperature are carefully controlled.

The physics occurring inside a solid source sublimation ampule are a complex coupled Multiphysics problem of fluid mechanics, heat transfer, and mass transfer. The flow and thermal characteristics of the ampoule have an effect on the mass transfer, and these effects are also closely coupled together and influence one another. Altering flow characteristics of the ampoule may change the distribution of where mass transfer occurs, therefore changing the heat load that drives the required thermal characteristics. Changing the thermal characteristics of the ampoule may change the distribution of vapor pressure across the sublimation surface impacting the concentration gradient and mass transfer into the carrier gas stream. Therefore, flow characteristics and thermal characteristics of the ampoule are considered in tandem. Thus, the ampoule design must ensure that the areas of the ampoule that have good flow characteristics are met with good thermal characteristics.

The thermal characteristics require ensuring that the ampoule allows for sufficient heat transfer to the precursor surface to prevent significant surface cooling from latent heat extracted during sublimation. The highest heat fluxes will be found in the areas with the highest mass transfer. Failure of the ampoule to provide great enough heat transfer will result in greater temperature decrease of the sublimation surface, thereby reducing the sublimation rate. The vapor pressure of a precursor is typically described by the Antoine Equation which has an exponential relationship between vapor pressure and temperature. A small decrease in temperature therefore results in a large decrease in vapor pressure and reduces the mass transfer rate. Therefore, the thermal characteristics of the ampoule must ensure that high rates of heat transfer are possible between the heat source and the areas of highest mass transfer. Generally the ampoule materials of construction are of much higher thermal conductivity than the precursor itself. Precursor that is in contact or close to the wall of the ampoule generally maintains a higher temperature than precursor further from that wall. The heat source is typically in communication with the external surfaces of the ampoule, so the problem of thermal characteristics involves conducting heat from the outside of the ampoule to the surface of the precursor with the highest flux rates.

A single large bulk chamber filled with precursor has poor thermal characteristics because any material that sublimes away from the walls will need to conduct through a large path length of low thermal conductivity precursor resulting in large temperature drops in the center of the vessel. To resolve this issue, prior art sublimation ampoules may utilize trays, fins, or other protrusions to enhance the ratio of the surface area of precursor in contact with high thermal conductivity material to volume of the precursor.

The problem of solid source precursor delivery is further complicated by consistency of delivery rate over the life of the ampoule. Prior art solid source delivery systems provide adequate initial delivery rate performance, however as precursor depletes, the delivery rate decreases, which necessitates complex adjustments to the flow characteristics and thermal characteristics of the system.

By way of example, as solid precursor depletes quicker from certain areas, it can alter the way carrier gas flows through the ampoule, thereby changing its flow characteristics. This can also result in a change the conduction path of heat to the sublimation surface due to walls of the ampoule conducting heat better than a center of the ampoule. If precursor is initially in contact with the wall of the vessel, these areas will be the hottest and promote mass transfer. Once enough material sublimes and contact is lost with the wall of the vessel, heat will no longer conduct directly to that surface. Heat will either have to convect or radiate across the gap, which may be negligible with the vacuum process conditions and relatively small temperature differences. Otherwise, the heat will have to conduct a much longer distance to the precursor surface, such as from the bottom of the vessel to the precursor surface. When this occurs, larger temperature gradients will form versus when the heat is conducted directly from wall of the vessel. With lower surface temperatures, the mass transfer is impacted and the delivery rate may change, upsetting the customer's deposition process.

Therefore, the design of a solid source ampoule must carefully consider the balance of all three of the transport phenomena: flow, thermal, and mass transfer. Each of them has a bidirectional coupling impacting one another. All of these elements must be carefully weighed by the designer to provide optimal performance. Not only to provide full saturation of the carrier gas upon initial install, but to ensure that the saturation of the carrier gas does not change throughout the lifetime of the ampoule. It is desirable to provide consistent delivery rate throughout the life of the ampoule with a secondary goal of achieving maximum saturation.

Prior art systems which utilize trays, fins, or other protrusions to promote sublimation are difficult to disassemble, reassemble, clean and refill. By way of example, each tray must be removed individually for cleaning and often involve many nooks and crannies that are difficult to clear from precursor residue. Conversely, when filling the vessel, trays must be individually filled and assembled in an inert environment such as a glovebox. Such complex cleaning and refilling processes result in greater downtime and tooling. Furthermore, complex ampoule configurations with intricate internals hinder the cleaning and fill operations, but they occupy precious volume inside the vessel that could otherwise be filled with solid precursor.

Therefore, there is a need to improve flow characteristics and thermal characteristics of solid precursor ampoules.

### BRIEF DESCRIPTION

In one aspect of the present disclosure, a sublimation ampoule is disclosed. The ampoule includes a sublimation container and a container lid. The sublimation container has an open end and a closed end, a sidewall and at least two chambers extending between the open end and the closed end. Each chamber is separated by a container wall and each chamber having a surface area and a sublimation rate. The container lid has a top surface and a bottom surface defining a thickness. The bottom surface removably securable to the open end of the sublimation container forming a fluid seal.

The container lid further includes a lid inlet positioned on the top surface of the container lid, where the lid inlet extending through the thickness. The container lid further includes a lid outlet positioned on the top surface of the container lid the lid outlet extending through the thickness. The container lid further includes at least one chamber inlet positioned on the bottom surface of the container lid fluidly connected to the lid inlet. Each chamber inlet is fluidly connected to a chamber of the at least two chambers, and each chamber inlet has a cross-sectional area. The container lid further includes a conduit having a conduit inlet and a conduit outlet positioned on the bottom surface. The conduit inlet and conduit outlet extend partially into the thickness, and the conduit fluidly connects to two chambers of the at least two chambers. The conduit has cross-sectional area. The sublimation rate of each chamber is defined by the surface area of each chamber, a temperature of each chamber, and the headspace pressure of each chamber, and the sublimation rate of each chamber is substantially equal.

In another aspect of the present disclosure, a sublimation ampoule is disclosed. The sublimation ampoule includes a sublimation container and a sublimation lid. The sublimation container has an open end and a closed end, a sidewall, and a central longitudinal axis. The sublimation container includes an interior wall extending across the sidewall of the sublimation container; a radial wall radial wall concentric with the central longitudinal; a first chamber and a second chamber separated by the interior wall and, a third chamber and a fourth chamber and are separated from the first chamber and second chamber by the radial wall, and adjacent to the sidewall of the sublimation container. The container lid has a top surface and a bottom surface defining a thickness. The bottom surface is removably securable to the open end of the sublimation container forming a fluid seal. The container lid includes a lid inlet positioned on the top surface of the container lid having a fixed inlet flow rate, the lid inlet extending through the thickness; at least one chamber inlet positioned on the bottom surface of the container lid fluidly connected to the lid inlet, the chamber inlet in fluid communication with the first chamber; the chamber inlet having a cross-sectional area; a lid outlet positioned on the top surface of the container lid having a fixed outlet pressure, the lid outlet extending through the thickness and in fluid communication with the fourth chamber; and. The container lid further includes a plurality of conduits having a conduit inlet and a conduit outlet positioned on the bottom surface, the conduit inlet and conduit outlet extending partially into the thickness, the conduit fluidly connecting the first chamber, the second chamber. The third chamber and the fourth chamber, each of the plurality of conduits having cross-sectional area. The sublimation rate of each chamber is defined by the surface area of each chamber, a temperature of each chamber, and the headspace pressure of each chamber, and the sublimation rate of each chamber is substantially equal.

### BRIEF DESCRIPTION OF THE DRAWINGS

The subject-matter of the disclosure will be explained in more detail in the following text with reference to exemplary embodiments which are illustrated in the attached drawings.

FIG. 1 illustrates a perspective view an exemplary sublimation ampoule in accordance with one or more embodiments of the present disclosure;

FIG. 2 illustrates a cross-sectional view of the sublimation ampoule of FIG. 1 taken along cross-section line X-X′;

FIG. 3 illustrates an exploded view of the sublimation ampoule of FIG. 1;

FIG. 4 illustrates a top view of a container of the sublimation ampoule of FIG. 1;

FIG. 5 illustrates a top view of a lid of the sublimation ampoule of FIG. 1 positioned over the container;

FIGS. 6A through 6D illustrate cross-sectional schematic views of the sublimation ampoule of FIG. 1 taken along cross-section line X-X′, with emphasis on lid configurations;

FIG. 7A illustrates an ampoule having two chambers with the same surface area;

FIG. 7B illustrates an ampoule having three chambers;

FIG. 7C illustrates an ampoule having four chambers;

FIG. 8 illustrates an ampoule having two chambers with non-equal surface area;

FIG. 9A illustrates an ampoule having two chambers with the same surface area;

FIG. 9B illustrates an ampoule having three chambers with the same surface area;

FIG. 10 illustrates an ampoule having two chambers with the same surface area;

FIG. 11 illustrates an ampoule having two chambers having a first chamber and a second chamber separated by a radial wall;

FIG. 12 illustrates an ampoule having an interior wall separating the container into two halves, and a radial wall further separating the container to define four chambers;

FIG. 13 illustrates an ampoule having two interior walls separating the container into four halves, and a radial wall further separating the container to eight chambers; and,

FIG. 14 illustrates a precursor delivery system in accordance with one or more embodiments of the present disclosure.

The reference symbols used in the drawings, and their meanings, are listed in summary form in the list of reference symbols. In principle, identical parts are provided with the same reference symbols in the figures.

### DETAILED DESCRIPTION

In the following specification and the claims, reference will be made to a number of terms, which shall be defined to have the following meanings.

As used herein, the singular forms “a,” “an,” and “the” include plural references unless the context clearly dictates otherwise. The terms “comprising,” “including,” and “having” are intended to be inclusive and mean that there may be additional elements other than the listed elements. The terms “optional” or “optionally” means that the subsequently described event or circumstance may or may not occur, and that the description includes instances where the event occurs and instances where it does not.

Unless otherwise indicated, approximating language, such as “generally,” “substantially,” and “about,” as used herein indicates that the term so modified may apply to only an approximate degree, as would be recognized by one of ordinary skill in the art, rather than to an absolute or perfect degree. Accordingly, a value modified by a term or terms, such as “about,” “approximately,” and “substantially,” is not to be limited to the precise value specified. In at least some instances, the approximating language may correspond to the precision of an instrument for measuring the value. Here and throughout the specification and claims, range limitations may be identified. Such ranges may be combined and/or interchanged, and include all the sub-ranges contained therein unless context or language indicates otherwise.

Additionally, unless otherwise indicated, the terms “first,” “second,” etc. are used herein merely as labels, and are not intended to impose ordinal, positional, or hierarchical requirements on the items to which these terms refer. Moreover, reference to, for example, a “second” item does not require or preclude the existence of, for example, a “first” or lower-numbered item or a “third” or higher-numbered item.

Embodiments of the disclosure are directed to a multi-chamber sublimation ampoule including a sublimation container and a container lid. The container has an open end and a closed end, a sidewall defining least two chambers extending between the open end and the closed end. Each chamber is separated by a container wall, and each chamber has a surface area and a sublimation rate. The container lid has a top surface and a bottom surface defining a thickness, and the bottom surface removably securable to the open end of the sublimation container forming a fluid seal.

The container lid further includes a lid inlet positioned on the top surface of the container lid, a lid outlet positioned on the top surface of the container lid the lid outlet extending through the thickness; and at least one chamber inlet positioned on the bottom surface of the container lid fluidly connected to the lid inlet, each chamber inlet is fluidly connected to a chamber of the at least two chambers, and each chamber inlet has a cross-sectional area. The container lid further includes a conduit having a conduit inlet and a conduit outlet positioned on the bottom surface. The conduit inlet and conduit outlet extend partially into the thickness, and the conduit fluidly connects to two chambers of the at least two chambers, the conduit having cross-sectional area.

Carrier gas is supplied to the ampoule by the lid inlet and becomes progressively saturated through the sublimation process with vaporized precursor as the carrier gas passes between chambers from the conduit of the lid. The sublimation rate of each chamber is defined by the relative surface area of each chamber, the relative temperature gradient of each chamber, and the headspace pressure of each chamber (which is a function of the transfer restrictions between chambers). The present disclosure enables each chamber to have a substantially equal sublimation rate such that each chamber fully depletes over the lifetime (operation) of the sublimation ampule. As used herein, the term “sublimation rate” denotes a measurement of amount of solid precursor sublimed (depleted) from a chamber as a function of time and is measured in mg/min/cm² (mass sublimed over time over surface area) in SI units. The present disclosure also takes into consideration the volume of solid precursor in each chamber, and for the purposes of the present disclosure, each chamber is filled to the same level.

It is understood that the sublimation rate (as a function of the relative surface area of each chamber, the relative temperature gradient of each chamber, and the headspace pressure of each chamber) results in equalized sublimation rate under ideal conditions. However, as previously set forth, the sublimation process is a complex coupled Multiphysics problem of fluid mechanics, heat transfer, and mass transfer, and secondary factors may affect the sublimation rate of each chamber. In practice, the sublimation rate may thus be slightly unequal sublimation due to secondary factors outside of the scope of this disclosure. In instances where sublimation is not equal due to external factors (resulting in up to 20% remaining solid precursor in a chamber), less solid precursor material can be filled into the chambers which may otherwise not be fully depleted, such that the entire ampoule fully depletes regardless. Stated differently, to achieve equal sublimation rates in non-ideal conditions, the error between chambers can be remedied by adding less precursor material to those chambers. Ideal conditions are calculated and optimized by computer-aided simulations and finite element analysis. Real conditions (not-ideal conditions) are observed and determined through prototyping and pilot testing.

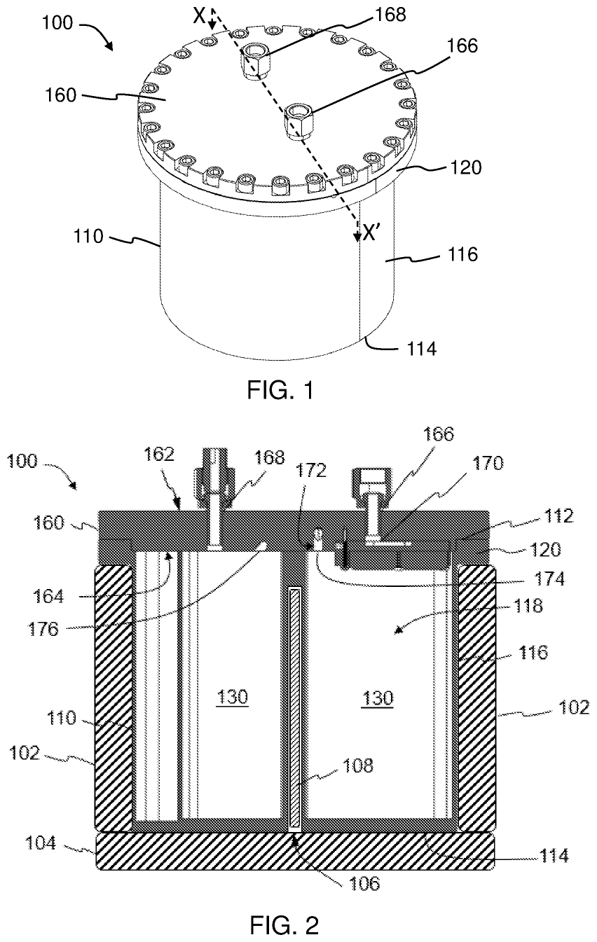

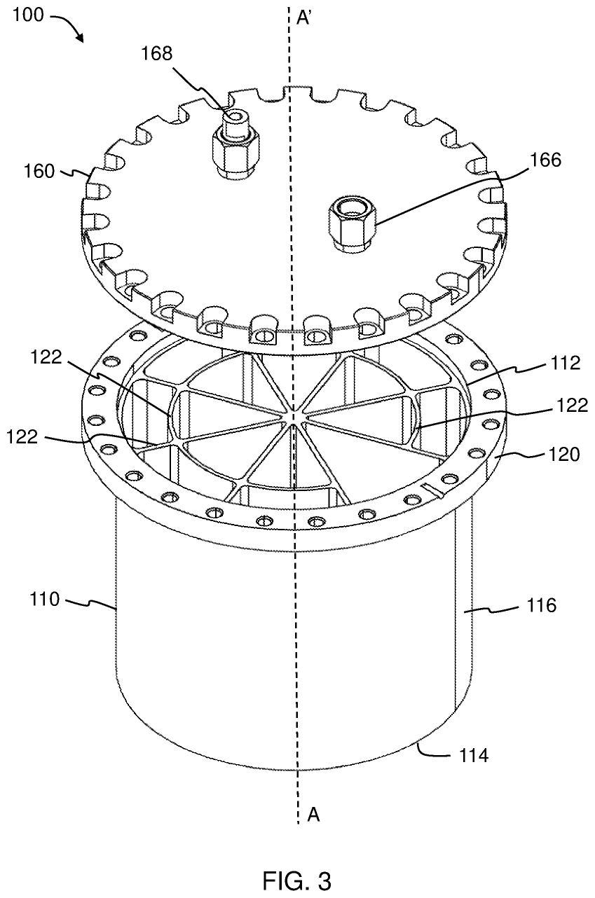

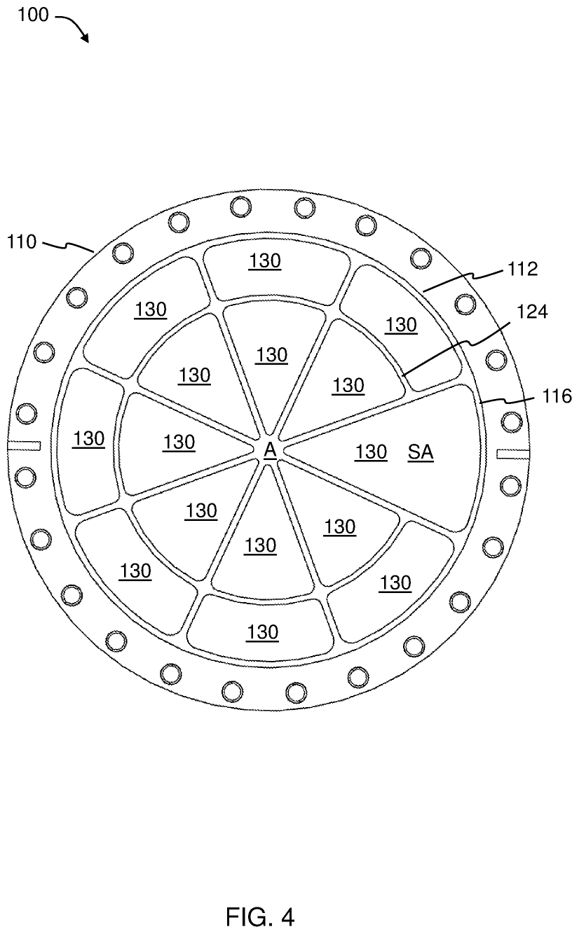

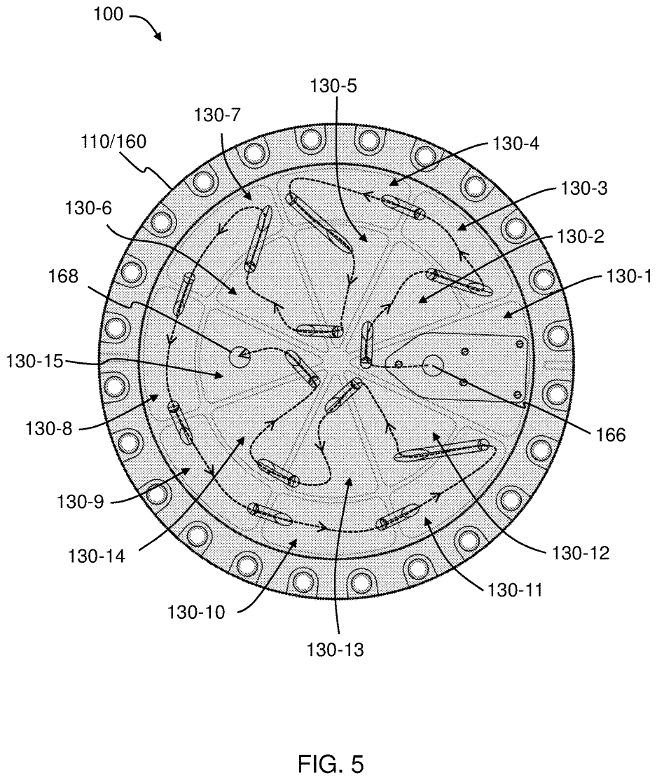

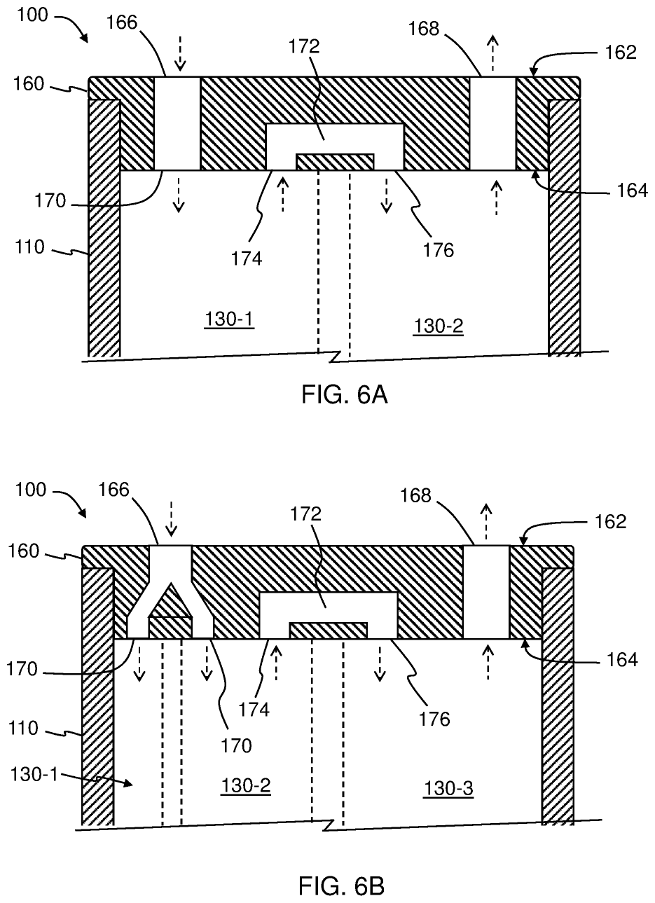

FIGS. 1 through 5 illustrate an exemplary multi-chamber sublimation ampoule 100 (hereinafter referred to as ampoule 100) in accordance with one or more embodiments of the present disclosure. FIG. 1 illustrates a perspective view; FIG. 2 illustrates a cross-sectional view of FIG. 1 taken along cross-section line X-X′ and FIG. 3 illustrates an exploded view of the ampoule 100. The ampoule 100 includes a multi-chamber sublimation container 110 (hereinafter referred to as container 110) and a container lid 160 (hereinafter referred to as lid 160). FIG. 4 illustrates a top view of the container 110 and FIG. 5 illustrates a top view of the lid 160 positioned over the container 110.

The container 110 includes an open end 112, a closed end 114 and a sidewall 116 defining an interior cavity 118 of the container 110. In some embodiments, the open end 112 includes a flange 120 for securing or fastening the container 110 to the lid 160. In some embodiments, the closed end 114 and sidewall 116 define a unitary cylindrical body. In some embodiments, the closed end 114 is fastened to the sidewall 116 such that the closed end 114 can be removed from the sidewall 116 for cleaning and refilling of the interior cavity 118. Side heaters 102 are positioned around the ampoule 100 and a bottom heater 104 is positioned adjacent to the closed end 114 to facilitate heating of the sidewall 116 of the sublimation container 110. In some embodiments an aperture 106 extends from the closed end 114 a distance into the container 110. A cartridge heater 108 can be disposed within the aperture 106 to internally heat the container 110. Heat output of the side heaters 102, the bottom heater 104 and the cartridge heater 108 may be increased or decreased in response to changes to mass flow and fluid flow properties during the sublimation process.

The container 110 includes at least two chambers 130 extending between the open end 112 and the closed end 114. The at least two chambers 130 are separated by a container wall 122 disposed within the cavity 118, and each of the at least chambers 130 have a surface area. The surface area is in reference to and parallel with the open end 112. Because the sidewall 116 and the container wall 122 are perpendicular to the open end 112, the surface area is consistent for each chamber between the open end 112 and the closed end 114. The sublimation rate for each chamber of the at least two chambers 130 is dependent on (for the purposes of this disclosure) relative surface area of each chamber, the relative temperature gradient of each chamber, and the headspace pressure of each chamber

The terms “at least two chambers,” “a plurality of chambers,” “two or more chambers” and “chambers” generally are used interchangeably and are denoted by reference numeral “130.” As used herein, a chamber of the at least two chambers 130 is denoted by reference “130-n” where “n” denotes an integer number corresponding to a chamber of the at least two chambers. Therefore, a first chamber is “130-1”, a second chamber is “130-2” and an nth chamber is “130-n”. The first chamber 130-1 is in fluid communication with an inlet 166 of the lid 160. The second chamber 130-2 is in fluid communication with the first chamber 130-1 by one or more conduits 172 of the lid 160, and the nth chamber 130-n (a last chamber) is in fluid communication with an outlet 168 of the lid 160. The nth chamber is downstream from the first chamber, and intermediate chambers are between the first chamber and the nth chamber.

As explained in further detail below, the chambers 130 may be in a series or parallel configuration with respect to the carrier gas entering or exiting the chambers, and therefore the first two chambers (130-1, 130-2) in some embodiments may both be in fluid communication with the inlet 166 of the lid 160 in tandem. Likewise, any two or more chambers 130 may be in fluid communication with a single conduit 172 or with an outlet 168 of the lid 160.

The lid 160 includes a top surface 162 and a bottom surface 164 defining a thickness. The bottom surface 164 is removably securable to the open end 112 (and the flange 120) of the container 110 forming a fluid seal. The lid 160 further includes a lid inlet 166 positioned on the top surface 162 of the lid 160, and a lid outlet 168 positioned on the top surface 162 of the lid 160. The lid inlet 166 and the lid outlet 168 extend through the thickness of the lid 160 and facilitate fluid connection of the ampoule 100 to a precursor delivery system (not shown). The lid inlet 166 is in fluid communication with at least one chamber inlet 170 positioned on the bottom surface 164 of the lid 160, and each chamber inlet 170 is fluidly connected to a chamber of the at least two chambers 130 of the container 110.

Carrier gas is supplied to the lid inlet 166 and is dispersed to the at least one chamber inlet 170 and into a corresponding chamber of the at least two chambers 130. Generally. each chamber inlet 170 has a cross-sectional area which defines a headspace pressure of each chamber inlet 170 (among other parameters, which include the pressure of the carrier gas supplied to the lid inlet 166). In some embodiments, the lid inlet 166 is fluidly connected to a single chamber inlet 170. In some embodiments, the lid inlet 166 is connected to at least two chamber inlets 170 in a parallel configuration. Generally, the cross-sectional area of the at least two chamber inlets 170 are equal, resulting in equal distribution of the carrier gas from the lid inlet 166.

The lid 160 further includes a plurality of conduits 172 extending across the thickness of the lid 160 to connect the chambers 130 to one another. Each conduit 172 includes at least one conduit inlet 174 and at least one conduit outlet 176 positioned on the bottom surface 164. The conduit inlet 174 and conduit outlet 176 extend partially into the thickness of the lid 160 to facilitate connections between chambers 130.

As shown in FIG. 4, the container wall 122 can include radial walls 124 and interior walls 126 to subdivide the container 110 into the chambers 130. In the illustrated embodiment, the radial walls 124 are concentric with a longitudinal axis A-A′ (also illustrated n FIG. 2), and the interior walls 126 extend through the longitudinal axis A-A′ and contact the sidewall 116 of the container 110 on opposite sides within the interior cavity 118. The radial walls 124 and interior walls 126 are made from thermally conductive materials which promote heat transfer from the side heaters 102 (of FIG. 1) to the interior of the container 110.

As will be explained in further detail below, chambers 130 which are adjacent to the sidewall 116 of the container 110 are heated to a greater temperature relative to chambers 130 which are interior to the radial wall 124. Therefore, chambers 130 adjacent to the sidewall 116 of the container 110 have a substantially equal temperature gradient.

By utilizing multiple chambers 130 in a single container 110 and connecting them in series or parallel via conduits 172 of the lid 160, the latent cooling effect in upstream or adjacent chambers 130 is isolated from the subsequent chambers 130 resulting in better thermal characteristics of the subsequent chambers 130. The thermal characteristics are also improved in the subsequent chambers because the carrier gas is reheated as it travels through the lid 160 between chambers 130. Furthermore, by directing the carrier gas at the surface of multiple chambers 130, adequate surface area is achieved for the carrier gas to become fully saturated. The flow into each chamber is directed downwards at the surface area of the solid precursor to provide good flow characteristics. Furthermore, the flow into each of the chamber 130 is directed into a location of the surface to balance these two characteristics to ensure sublimation occurs evenly across the surfaces and changes little in time.

In many ampoule heating applications, the lid is kept hotter than the base to prevent condensation from occurring on the lid. Therefore, by routing the carrier gas between chambers through the lid allows for the ability to superheat the carrier gas hotter than would be possible with the carrier gas routed between chambers below the lid. The reheated carrier gas brings more energy to the sublimation surface to enhance sublimation in the latter chambers which would otherwise have naturally less sublimation. The precursor vapors typically have higher specific heat capacity than that of the carrier gas. When transferring between chambers, the carrier gas has some precursor vapor from the initial chamber(s) which results in the mixture having a higher heat capacity than the carrier gas further enhancing the heat transfer to the sublimation surface in the subsequent chamber.

As shown in FIG. 5, carrier gas is supplied into the ampoule 100 by inlet 166. The path the carrier gas follows between chambers is illustrated by dashed arrows. In this exemplary embodiment, all chambers (130-1 to 130-15) are each connected in series via conduits 172, with the first chamber 130-1 receiving carrier gas from the inlet 166 and the fifteenth chamber 130-15 receiving carrier gas from the upstream fourteenth chamber 130-14. The carrier gas becomes increasingly saturated with vaporized precursor as the carrier gas passes through each chamber (130-1 to 130-15) and the solid precursor is sublimed. Fully saturated carrier gas exits from the fifteenth chamber 130-15 to the outlet 168. The embodiment shown in FIG. 5 is merely an exemplary illustration of the ampoule 100 and is not intended to be limiting.

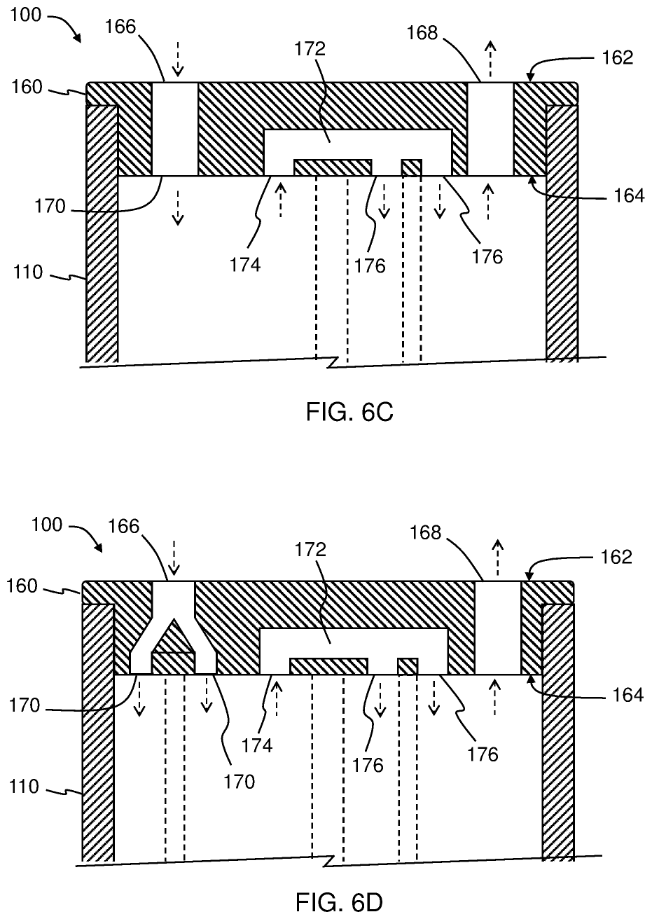

FIGS. 6A through 6D illustrate cross-sectional schematic views of the ampoule 100 taken along cross-section line X-X′, with emphasis on lid 160 configurations. As shown in FIG. 6A, the lid inlet 166 is positioned on the top surface 162 of the lid 160, and the lid outlet 168 is positioned on the top surface 162 of the lid 160. The lid inlet 166 and the lid outlet 168 extend through the thickness of the lid 160, and the lid inlet 166 is in fluid communication with one chamber inlet 170. The conduit 172 extends across the thickness, and both the conduit inlet 174 and conduit outlet 176 extend into the thickness to facilitate fluid communication between chambers (130-1, 130-2) in a series configuration. In the configuration of FIG. 1, carrier gas is supplied to the first chamber 130-1, and the carrier gas subsequently enters the second chamber 130-2. The carrier gas then exits the ampoule 100 by the lid outlet 168.

As shown in FIG. 6B, the lid inlet 166 is in fluid communication with two chamber inlets 170, each of the chamber inlets 170 in fluid communication with a first chamber 130-1 and a second chamber 130-2 defining a parallel configuration. Both of the first chamber 130-1 and second chamber 130-2 are in fluid connection with the third chamber 130-3 by the conduit 172. In the illustrated embodiment, the carrier gas exits the third chamber 130-3 by the lid outlet 168. Because FIG. 6B is shown in two dimensions, the fluid connection between the first chamber 130-1 and the third chamber 130-3 is not shown.

As shown in FIG. 6C, the lid inlet 166 is in fluid communication with one chamber inlet 170, and the conduit 172 includes two conduit outlets 176. The lid inlet 166 to one chamber inlet 170 define a series configuration, and the conduit 172 having two conduit outlets 176 define a parallel configuration.

As shown in FIG. 6D, the lid inlet 166 is in fluid communication with two chamber inlets 170, and the conduit 172 includes two conduit outlets 176, defining series configurations. In some embodiments, the lid inlet 166 can be connected to at least two chamber inlets 170. In some embodiments, the conduit 172 includes at least two conduit outlets 176.

Generally, each conduit 172 has a cross-sectional area which defines a headspace pressure of the corresponding chamber. The headspace pressure is therefore a function of the cross-sectional area of the conduit 172 and the headspace pressure from upstream chambers 130. In some embodiments, the conduit outlet 176 can include provisions for a fitting or a showerhead to selectively adjust the flow characteristics of carrier gas passing through the conduit outlet 176. The showerhead is a device for evenly distributing gasses across a greater surface area. The showerhead includes an inlet fitting which is removably connected to the conduit outlet 176 and a perforated outlet having a greater surface area than the inlet of the showerhead. It is understood that the headspace pressure of any of the chambers 130 is directly or indirectly affected by the cross-sectional area of the chamber inlet 170, and the cross-sectional area of downstream conduits 172. For purposes of the present disclosure, parameters that influence headspace pressure for any given chamber is referred to as “transfer restrictions” between chambers 130.

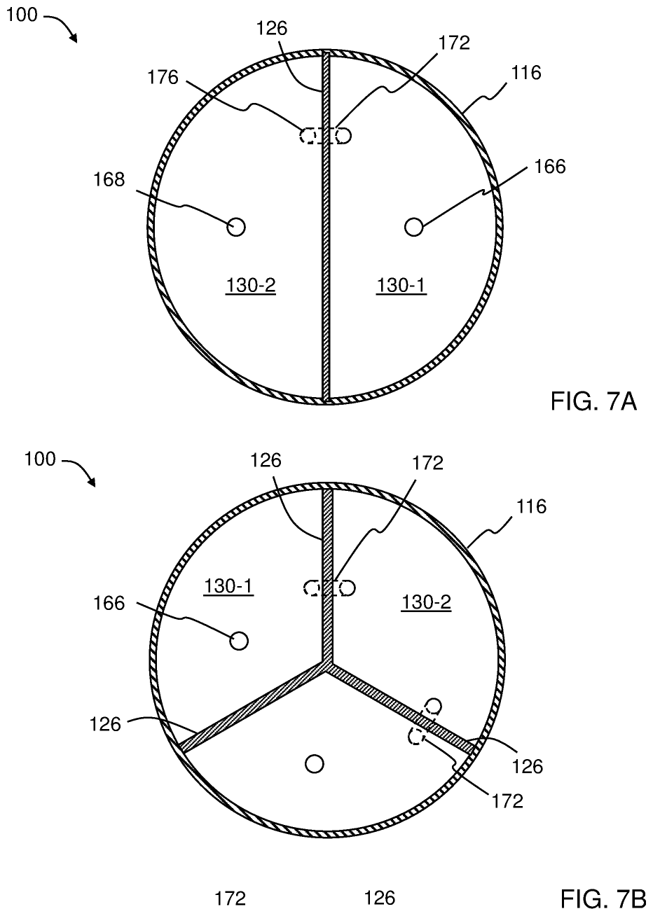

FIGS. 7A through 7C, FIG. 8, FIG. 9—illustrate top views of embodiments of the ampoule 100 in which the sublimation rate between chambers 130 is substantially equal by adjusting one or more of the following parameters: (1) modifying transfer restrictions between chambers 130, (2) adjusting the relative surface area of the chambers 130, (3) and by the relative temperature gradient of the chambers 130. As will be explained in further detail below, placement of chambers in series or parallel configurations also affect the sublimation rate. Finally, the further subdivision of the container 110 into additional chambers 130 also affects the sublimation rate. The ampoule 100 can have any number of chambers 130 facilitated by the illustrated configurations of radial walls 124 and interior walls 126.

Generally, transfer restrictions between chambers can be modified by increasing or decreasing the cross-sectional area of the conduits 172, the addition of additional conduits 172 between chambers 130 such that chambers 130 have a parallel configuration, and by the use of fittings and showerheads to the conduit outlet 176 and/or the lid inlet 166. Adjusting relative surface areas between chambers 130 is determined by the configurations of radial walls 124 and interior walls 126. The relative temperature gradient of the chambers 130 is determined by the proximity of chambers placement of the chambers 130 relative to the sidewall 116 and the side heaters 102 (as shown in FIG. 1).

FIG. 7A illustrates an ampoule 100 having two chambers (130-1, 130-2) with the same surface area, and therefore have the same volume. The first chamber 130-1 and the second chamber 130-2 are separated by an interior wall 126 such that the first chamber 130-1 and second chamber 130-2 have the same surface area. The first chamber 130-1 is in a series configuration with the second chamber 130-2 by one conduit 172 connecting the two chambers (130-1, 130-2).

Because both chambers (130-1, 130-2) are adjacent to the sidewall 116, both chambers (130-1, 130-2) have the same temperature gradient. To equalize the sublimation rate between chambers (130-1, 130-2), the transfer restriction between the chambers (130-1, 130-2) is increased, thereby lowering the sublimation flux in first chamber 130-1 to match the sublimation flux of the second chamber 130-2. Generally, increasing the transfer restriction raises the pressure in upstream chambers 130, which limits mass transfer in the upstream chambers 130. The first chamber 130-1 has a high saturation due to the headspace pressure from the lid inlet 166, but the saturation is reduced due to the headspace pressure downstream from the fist chamber 130-1. Thus, the limit to saturation in the first chamber 130-1 results in reduced mass transfer to balance the chambers (130-1, 130-2). To reduce the transfer restriction between the chambers (130-1, 130-2), the cross-sectional area of the conduits 172 can be smaller or a restriction fitting can be added to the conduit outlet 176.

The same concepts can be applied to multiple chambers 130 connected in series. FIG. 7B illustrates an ampoule 100 having three chambers (130-1, 130-2, 130-3). FIG. 7C illustrates an ampoule 100 having four chambers (130-1, 130-2, 130-3, 130-4). For both of the embodiments shown in FIGS. 7B and 7C, the interior walls 126 subdivide the chambers 130 into equal surface areas, each of the chambers 130 having the same volume. Adjacent chambers 130 are connected in series by one conduit 172 between the chambers 130. Because the chambers 130 are all adjacent to the sidewall 116, the chambers 130 have the same temperature gradient.

The first chambers 130-1 have the highest sublimation rates due to highest gas concentration gradients from the lid inlet 166. To limit saturation of the first chambers 130-1 and to equalize sublimation rates with downstream chambers 130, the transfer restrictions of downstream chambers can be progressively greater. To reduce the transfer restriction between downstream chambers 130, the cross-sectional area of the conduits 172 can be smaller or a restriction fitting can be added to the conduit outlet 176. Thus, the conduit 172 between the first chamber 130-1 and the second chamber 130-2 will have a cross-sectional area greater than a cross-sectional area of the conduit 172 between the second chamber 130-2 and the third chamber 130-3. This configuration can be scaled for any number of additional chambers 130 having the same surface area. Experimental data has indicated that the above configurations are valid with up to sixteen chambers.

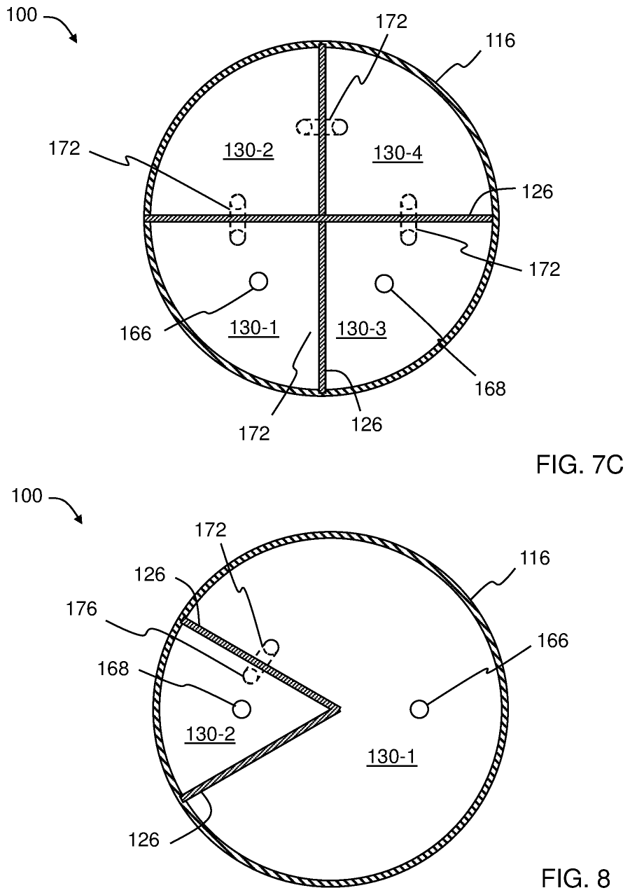

FIG. 8 illustrates an ampoule 100 having two chambers (130-1, 130-2) with non-equal surface area, and therefore non-equal volume. The first chamber 130-1 and the second chamber 130-2 are separated by an interior wall 126 such that the first chamber 130-1 has a greater surface area than a surface area of the second chamber 130-2. The first chamber 130-1 is in a series configuration with the second chamber 130-2 by one conduit 172 connecting the two chambers (130-1, 130-2). Because both chambers (130-1, 130-2) are adjacent to the sidewall 116, both chambers (130-1, 130-2) have the same temperature gradient.

To equalize the sublimation rate between chambers (130-1, 130-2), the relative surface areas of the chambers (130-1, 130-2) is adjusted such that the sublimation flux of the second chamber 130-2 is greater than the first chamber 130-1. This configuration compensates for upstream chambers having the majority of the sublimation occurring and running dry before downstream chambers.

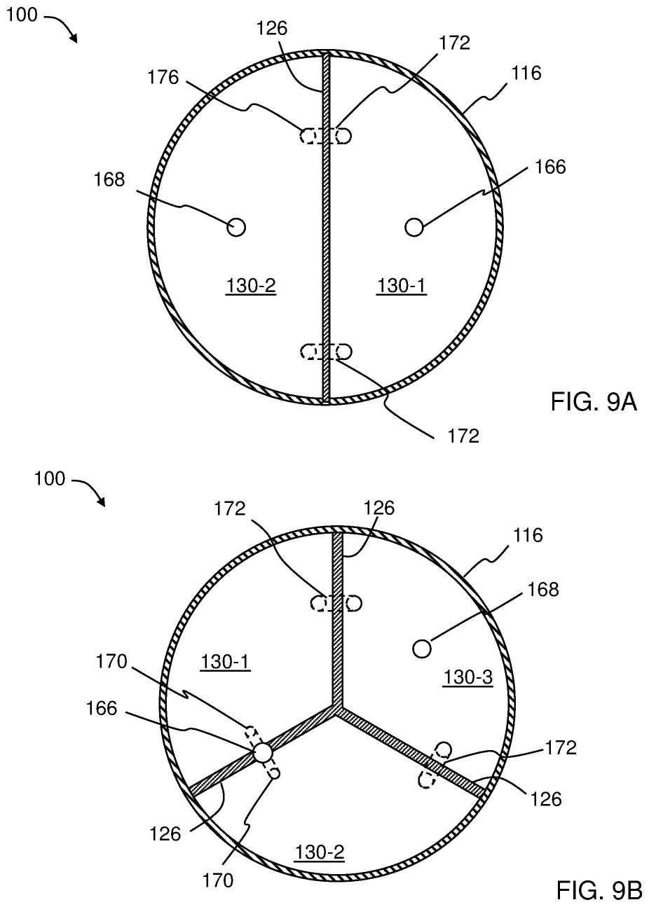

FIG. 9A illustrates an ampoule 100 having two chambers (130-1, 130-2) with the same surface area, and therefore have the same volume. The first chamber 130-1 and the second chamber 130-2 are separated by an interior wall 126 such that the first chamber 130-1 and second chamber 130-2 have the same surface area. The first chamber 130-1 is in a series configuration with the second chamber 130-2 by two parallel conduits 172 connecting the two chambers (130-1, 130-2).

Because both chambers (130-1, 130-2) are adjacent to the sidewall 116, both chambers (130-1, 130-2) have the same temperature gradient. To equalize the sublimation rate between chambers (130-1, 130-2), the transfer restriction between the chambers (130-1, 130-2) is increased, thereby lowering the sublimation flux in first chamber 130-1 to match the sublimation flux of the second chamber 130-2. By distributing the carrier gas more uniformly over the surface of the chambers by having multiple parallel conduits 172, the standard deviation of the sublimation flux is reduced. This concept can also be combined with varied transfer restriction between the conduits 172 similar to the embodiment of FIG. 7A, where the transfer restriction between the chambers (130-1, 130-2) is reduced (by reducing the cross-sectional area of the conduits 172).

FIG. 9B illustrates an ampoule 100 having three chambers (130-1, 130-2, 130-3) with the same surface area, and therefore have the same volume. The chambers 130-1, 130-2, 130-3) are separated by interior walls 126. The inlet 166 includes two chamber inlets 170 such that the first chamber 130-1 and the second chamber 130-2 are in a parallel configuration with respect to the inlet 166. Each of the first chamber 130-1 and the second chamber 130-2 are connected to the third chamber 130-3 by conduits 172. Because the chambers (130-1, 130-2, 130-3) are adjacent to the sidewall 116, the chambers (130-1, 130-2-130-3) have the same temperature gradient.

This embodiment combines the concept of multiple chambers as shown in FIGS. 7B and 7C, and the concept of parallel configurations of chambers of FIG. 9A. In particular, the first chamber 130-1 and the second chamber 130-2 have the highest sublimation rates due to highest gas concentration gradients from the lid inlet 166, and the saturation of the first chamber 130-1 and the second chamber 130-2 is limited by restricting the size of conduits 172 to the third chamber 130-3. The parallel configuration aids in reducing the standard deviation of the sublimation flux.

Thus, to equalize the sublimation rate between chambers (130-1, 130-2, 130-3), the transfer restriction between the first chamber 130-1 and the second chamber 130-2 to the third chamber 130-3 is increased. By distributing the carrier gas more uniformly over the surface of the chambers by having multiple parallel conduits 172, the standard deviation of the sublimation flux is reduced.

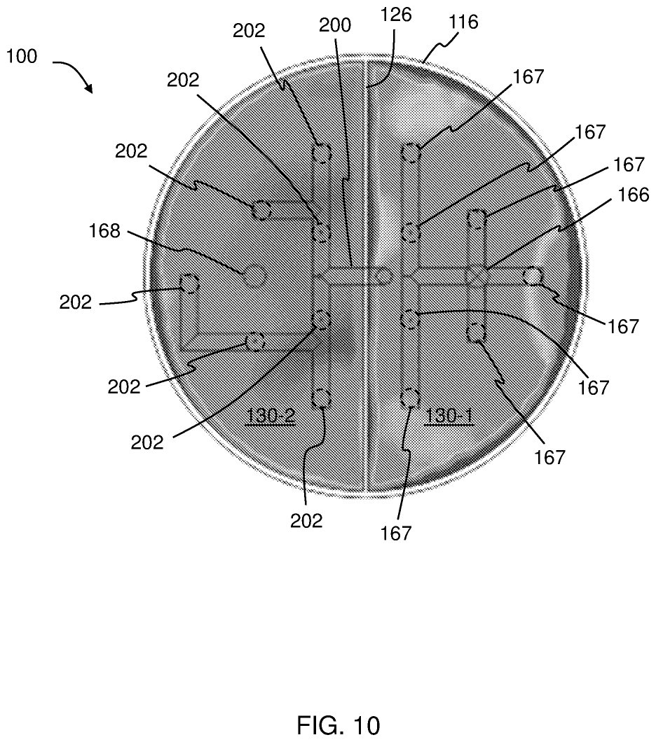

FIG. 10 illustrates an ampoule 100 having two chambers (130-1, 130-2) with the same surface area, and therefore have the same volume. The first chamber 130-1 and the second chamber 130-2 are separated by an interior wall 126 such that the first chamber 130-1 and second chamber 130-2 have the same surface area. The first chamber 130-1 is in a series configuration with the second chamber 130-2 by a conduit structure 200 connecting the two chambers (130-1, 130-2).

This embodiment illustrates the use of showerhead configuration for at least one of the inlet 166 and the conduit structure 200. In some embodiments, the lid 160 includes multiple chamber outlets 167 which evenly disperse carrier gas into the first chamber 130-1. In some embodiments, the conduit structure 200 includes multiple conduit outlets 202 which evenly disperse carrier gas into the second chamber 130-2. The distribution of carrier gas as a result of the showerhead configurations facilitates greater distribution uniformity of the carrier gas.

Because both chambers (130-1, 130-2) are adjacent to the sidewall 116, both chambers (130-1, 130-2) have the same temperature gradient. To equalize the sublimation rate between chambers (130-1, 130-2), the transfer restriction between the chambers (130-1, 130-2) is increased, thereby lowering the sublimation flux in first chamber 130-1 to match the sublimation flux of the second chamber 130-2. By distributing the carrier gas more uniformly over the surface of the chambers by having multiple parallel conduits 172, the standard deviation of the sublimation flux is reduced.

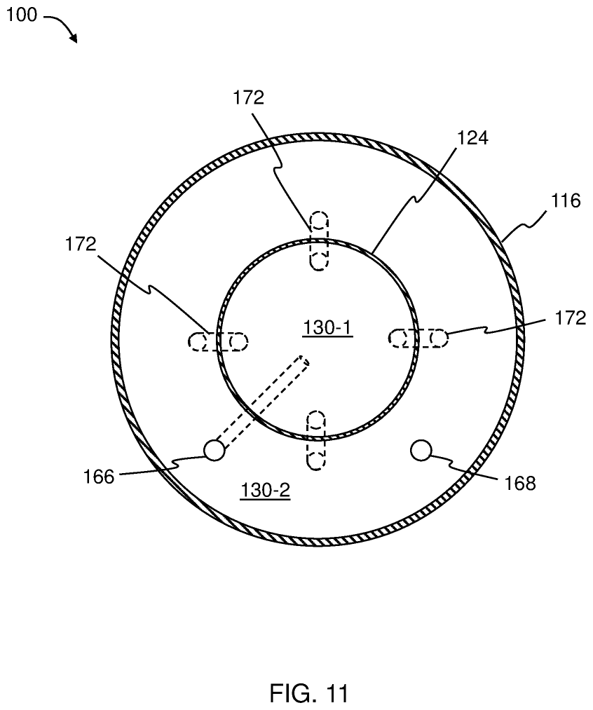

FIG. 11 illustrates an ampoule 100 having two chambers (130-1, 130-2) having a first chamber 130-1 and a second chamber 130-2 separated by a radial wall 124. The second chamber 130-2 is adjacent to the sidewall 116 and thus has a higher temperature gradient relative to the first chamber 130-1. In some embodiments, the first chamber 130-1 and the second chamber 130-2 have an equal surface area, and therefore the same volume. In some embodiments, the first chamber 130-1 and the second chamber 130-2 have a non-equal surface area. In some embodiments, the first chamber 130-1 and the second chamber 130-1 are connected in series with a single conduit 172. In some embodiments, the first chamber 130-1 and the second chamber 130-1 are connected in parallel with multiple conduits 172.

The sublimation rate of the first chamber 130-1 is increased due to the first chamber 130-1 being upstream from the second chamber 130-2 (similar to the embodiment of FIG. 7A). The sublimation rate of the second chamber 130-2 is increased due to the second chamber 130-2 having a higher temperature gradient.

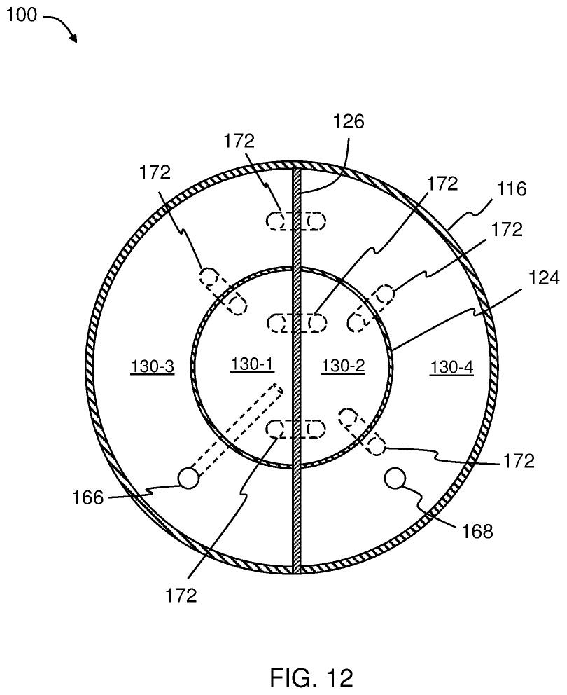

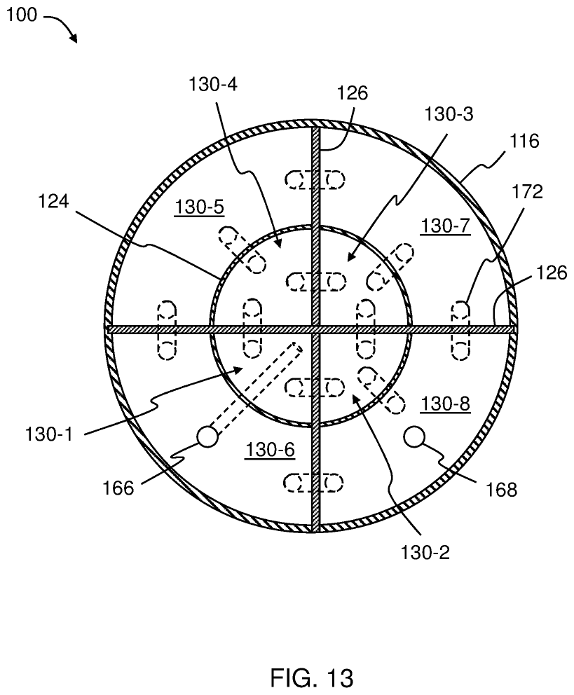

In some embodiments, the sublimation rates are equalized by increasing the transfer restriction of the second chamber 130-2. In some embodiments, the sublimination rates are equalized by increasing the surface area of the second chamber 130-2. In some embodiments, the sublimation rates are equalized by a combination of increasing the transfer restriction of the second chamber 130-2 and increasing the surface area of the second chamber 130-2. These concepts can be combined for more optimal ampoule configurations 100 as shown in FIGS. 12 and 13.

FIG. 12 illustrates an ampoule 100 having an interior wall 126 separating the container 110 into two halves, and a radial wall 124 further separating the container 110 to define four chambers (130-1, 130-2, 130-3, 130-4). The first chamber 130-1 and the second 130-2 are interior to the third chamber 130-3 and the fourth chamber 130-4.

The third chamber 130-3 and fourth chamber 130-4 are adjacent to the sidewall 116 and thus have a higher temperature gradient relative to the first chamber 130-1 and second chamber 130-2. In the illustrated embodiment, the first chamber 130-1 and the second chamber 130-2 have the same surface area. The third chamber 130-3 and the fourth chamber 130-4 have the same area. In some embodiments, the chambers (130-1, 130-2, 130-3, 130-4) have an equal surface area, and therefore the same volume. In some embodiments, the chambers (130-1, 130-2, 130-3, 130-4) have a non-equal surface area.

In the illustrated embodiment, the surface areas of the first chamber 130-1 and the second chamber 130-2 are less than the surface areas of the third chamber 130-3 and the fourth chamber 130-4. Similar to the embodiment of FIG. 8, the surface areas of the third chamber 130-3 and the fourth chamber 130-4 are greater than the surface areas of the first chamber 130-1 and the second chamber 130-2 to equalize, or at least partially equalize the sublimation rates of the third chamber 130-3 and the fourth chamber 130-4 relative to the first chamber 130-1 and the second chamber 130-2.

The sublimation rates of the chambers (130-1, 130-2, 130-3, 130-4) are further equalized due to the third chamber 130-3 and the fourth chamber 130-4 having a greater temperature gradient relative to the fist chamber 130-1 and second chamber 130-2, similar to the embodiment of FIG. 11.

Because upstream chambers (the first chamber 130-1 and the second chamber 130-2) have a higher sublimation rate relative to the downstream chambers (the third chamber 130-3 and the 130-4), the transfer restrictions of the downstream chambers (130-3, 130-4) can be increased by reducing the cross-sectional area of the conduits 172 connecting the chambers, similar to the embodiment of FIG. 7A.

In some embodiments, the chambers (130-1, 130-2, 130-3, 130-4) are connected in series with a single conduit 172 between chambers. In some embodiments, the chambers (130-1, 130-2, 130-3, 130-4) are connected in parallel with two or more conduits 172 between chambers. In some embodiments, a combination of single conduits 172 and multiple conduits 172 can be employed to facilitate series and parallel connections.

Thus, the sublimation rates can be equalized by modifying transfer restrictions between chambers 130, adjusting the relative surface area of the chambers 130, and by the relative temperature gradient of the chambers 130. In addition, the placement of chambers in series or parallel configurations also facilitate equalization of the sublimation rates. Finally, the further subdivision of the container 110 into additional chambers 130 also affects the sublimation rate, which is illustrated in FIG. 13.

FIG. 13 illustrates an ampoule having two interior walls 126 separating the container 110 into four halves, and a radial wall 124 further separating the container 110 to eight chambers (130-1, 130-2, 130-3, 130-4, 130-5, 130-6, 130-7, 130-8). The first chamber 130-1, second 130-2, third chamber 130-3 and the fourth chamber 130-4 are interior to the fifth chamber 130-5, sixth 130-6, seventh 130-7 and the eighth chamber 130-8. Thus, the fifth chamber 130-5, sixth 130-6, seventh 130-7 and the eighth chamber 130-8 have a higher temperature gradient relative to the first chamber 130-1, second 130-2, third chamber 130-3 and the fourth chamber 130-4 due to the proximity to the sidewall 116.

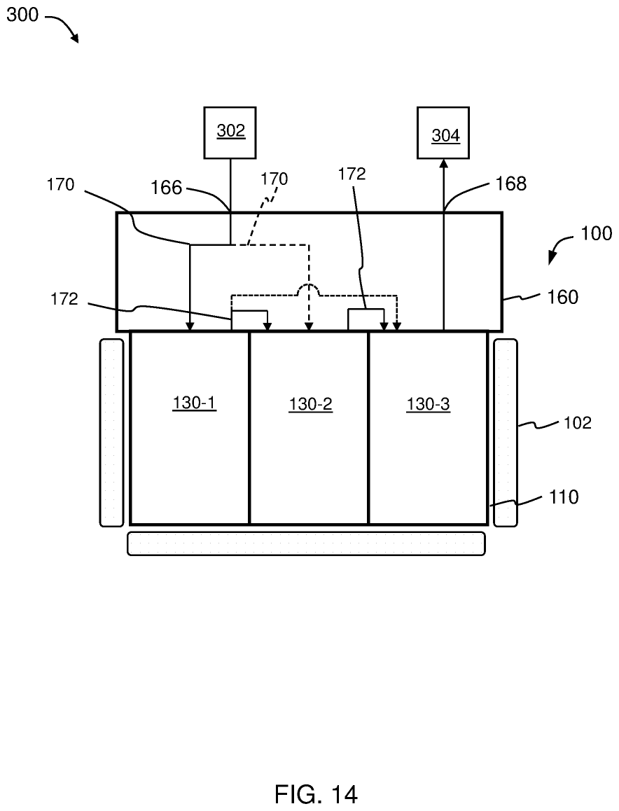

FIG. 14 illustrates a precursor delivery system 300 which includes the ampoule 100 of FIGS. 1 through 13. The system includes a carrier gas feed 302 to deliver carrier gas to the ampoule 100 and a carrier gas outlet feed 304. The system 300 regulates the concentration of carrier gas as well as the flow of carrier gas from the gas feed 302 such that saturated carrier gas exiting from the gas outlet feed 304 has a constant outlet flow and constant saturation. To effectuate sublimation within the ampoule 100, the system also regulates the temperature of the ampoule 100 by operation of the side heaters 102.

The ampoule 100 is schematically illustrated and includes at least three chambers (130-1, 130-2, 130-3). The inlet 166 can be connected to the first chamber 130-1 at least one chamber inlet 170 in a series configuration. Alternatively, the inlet 166 can connected to the first chamber 130-1 and the second chamber 130-2 by two chamber inlets 170 in a parallel configuration. Each chamber is connected to an adjacent chamber by conduits 172, and in some embodiments, adjacent chambers can be arranged in a parallel configuration by multiple conduits 172.

Each of the at least three chambers (130-1, 130-2, 130-3) has a surface area, a headspace pressure, and a sublimation rate. As previously set forth, the sublimation rates of each of the chambers (130-1, 130-2, 130-3) are equal. The sublimation rates are equalized by adjusting one or more of (1) modifying transfer restrictions between chambers 130, (2) adjusting the relative surface area of the chambers 130, (3) and by the relative temperature gradient of the chambers 130. Placement of chambers in series or parallel configurations also affect the sublimation rate. The further subdivision of the container 110 into additional chambers 130 also affects the sublimation rate. The ampoule 100 can have any number of chambers 130 facilitated by the illustrated configurations of radial walls and interior walls.

The methods, systems, and compositions disclosed herein are not limited to the specific embodiments described herein, but rather, steps of the methods, elements of the systems, and/or elements of the compositions may be utilized independently and separately from other steps and/or elements described herein.

Although specific features of various embodiments may be shown in some drawings and not in others, this is for convenience only. Moreover, references to “one embodiment” in the above description are not intended to be interpreted as excluding the existence of additional embodiments that also incorporate the recited features. In accordance with the principles of the disclosure, any feature of a drawing may be referenced and/or claimed in combination with any feature of any other drawing.

This written description uses examples, including the best mode, to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

Further aspects of the invention are provided by the subject matter of the following clauses:

A sublimation ampoule comprising: a sublimation container having an open end and a closed end, a sidewall and at least two chambers extending between the open end and the closed end, each chamber is separated by a container wall, each chamber having a surface area and a sublimation rate; and, a container lid having a top surface and a bottom surface defining a thickness, the bottom surface removably securable to the open end of the sublimation container forming a fluid seal, the container lid comprising: a lid inlet positioned on the top surface of the container lid, the lid inlet extending through the thickness; a lid outlet positioned on the top surface of the container lid the lid outlet extending through the thickness; at least one chamber inlet positioned on the bottom surface of the container lid fluidly connected to the lid inlet, each chamber inlet fluidly connected to a chamber of the at least two chambers, each chamber inlet having a cross-sectional area; and, conduit having a conduit inlet and a conduit outlet positioned on the bottom surface, the conduit inlet and conduit outlet extending partially into the thickness, the conduit fluidly connecting to two chambers of the at least two chambers, the conduit having cross-sectional area.

The sublimation ampoule of the preceding clause, wherein the sublimation rate of each chamber is defined by the surface area of each chamber, a temperature of each chamber, and the headspace pressure of each chamber, wherein the sublimation rate of each chamber is within 20% of the other chambers.

The sublimation ampoule of any preceding clause, wherein the sublimation rate of each chamber is defined by the surface area of each chamber, a temperature of each chamber, and the headspace pressure of each chamber, wherein the sublimation rate is equal.

The sublimation ampoule of any preceding clause, further comprising heaters to facilitate heating of the sidewall of the sublimation container.

The sublimation ampoule of any preceding clause, wherein the sublimation rate of each chamber is equal.

The sublimation ampoule of any preceding clause, wherein a surface area of a first chamber is equal to a surface area of a second chamber.

The sublimation ampoule of any preceding clause, wherein a headspace pressure of the first chamber is greater than a headspace pressure of the second chamber.

The sublimation ampoule of any preceding clause, wherein the cross-sectional area of the conduit connecting the first chamber to the second chamber is less than the cross-sectional area of the inlet.

The sublimation ampoule of any preceding clause, further comprising a radial wall concentric with a central longitudinal axis of the sublimation container, the radial wall separating the first chamber from the second chamber, the second chamber adjacent to the sidewall of the sublimation container.

The sublimation ampoule of any preceding clause, wherein the second chamber is heated at a greater temperature than a temperature of the first chamber, wherein the sidewall of the sublimation container is heated by heaters.

The sublimation ampoule of any preceding clause, wherein a surface area of a first chamber is greater than a surface area of a second chamber.

The sublimation ampoule of any preceding clause, wherein a headspace pressure of the first chamber is equal to a headspace pressure of the second chamber.

The sublimation ampoule of any preceding clause, further comprising an interior wall extending across the sidewall of the sublimation container, the interior wall separating the first chamber from the second chamber, wherein the first chamber and second chamber have the same temperature.

The sublimation ampoule of any preceding clause, further comprising a radial wall concentric with a central longitudinal axis of the sublimation container, the radial wall separating the first chamber from the second chamber, the second chamber adjacent to the sidewall of the sublimation container, wherein the second chamber is heated at a greater temperature than a temperature of the first chamber, wherein the sidewall of the sublimation container is heated by heaters.

The sublimation ampoule of any preceding clause, wherein the headspace pressure of the first chamber is greater than a headspace pressure of the second chamber.

The sublimation ampoule of any preceding clause, wherein the cross-sectional area of the conduit connecting the first chamber to the second chamber is less than the cross-sectional area of the inlet.

The sublimation ampoule of any preceding clause, further comprising a second conduit connecting the first chamber to the second chamber.

The sublimation ampoule of any preceding clause, wherein the closed end of the sublimation container is removably securable to the sidewall forming a fluid seal.

The sublimation ampoule of any preceding clause, further comprising an interior wall extending across the sidewall of the sublimation container, the interior wall separating the at least two chambers.

The sublimation ampoule of any preceding clause, further comprising a plurality of interior walls extending from a central longitudinal axis of the sublimation container to the sidewall of the sublimation container.

The sublimation ampoule of any preceding clause, further comprising a radial wall concentric with a central longitudinal axis of the sublimation container, the radial wall separating the at least two chambers.

The sublimation ampoule of any preceding clause, wherein a second chamber adjacent to the sidewall of the sublimation container is heated at a greater temperature than a temperature of a first chamber adjacent to the second chamber, the first chamber separated from the second chamber by the radial wall.

The sublimation ampoule of any preceding clause, wherein the lid inlet is fluidly connected to a first chamber of the at least two chambers, and the lid outlet is fluidly connected to a second chamber of the at least two chambers.

The sublimation ampoule of any preceding clause, wherein a third chamber is fluidly connected to the first chamber by a second conduit, and the third chamber is fluidly connected to the second chamber by a third conduit, and the second chamber is fluidly connected to the lid outlet.

The sublimation ampoule of any preceding clause, wherein the lid inlet is fluidly connected to a second chamber inlet of the at least one chamber inlet defining a parallel connection of chambers.

The sublimation ampoule of any preceding clause, wherein the conduit includes a conduit inlet and at least two conduit outlets defining a parallel connection of chambers.

The sublimation ampoule of any preceding clause further comprising at least one chamber outlet fluidly connected to the lid outlet, each chamber outlet fluidly connected to a chamber of the at least two chambers.

The sublimation ampoule of any preceding clause, wherein the sublimation container is subdivided into four chambers by an interior wall extending across the sidewall of the sublimation container and a radial wall concentric with a central longitudinal axis of the sublimation container.

The sublimation ampoule of any preceding clause, wherein a first chamber and a second chamber are separated by the interior wall, the first chamber in fluid communication with the lid inlet, the first chamber in fluid communication with the second chamber by at least one conduit.

The sublimation ampoule of any preceding clause, wherein a third chamber and a fourth chamber are adjacent to the sidewall of the sublimation container and are separated from the first chamber and second chamber by the radial wall, and the third chamber and forth chamber are separated by the interior wall, the fourth chamber in fluid communication with the lid outlet.

The sublimation ampoule of any preceding clause, wherein the third chamber and fourth chamber are in fluid communication by at least one conduit.

The sublimation ampoule of any preceding clause, wherein the third chamber and the first chamber are in fluid communication by at least one conduit.

The sublimation ampoule of any preceding clause, wherein the fourth chamber and the second chamber are in fluid communication by at least one conduit.

The sublimation ampoule of any preceding clause, wherein the third chamber and fourth chamber are heated at a greater temperature than a temperature of first chamber and second chamber.

The sublimation ampoule of any preceding clause, wherein the cross-sectional area of the conduit is less than the cross-sectional area of the lid inlet.

The sublimation ampoule of any preceding clause, wherein at least two conduits fluidly connect two chambers of the at least two chambers.

The sublimation ampoule of any preceding clause, wherein the conduit outlet includes a showerhead.

The sublimation ampoule of any preceding clause, wherein the conduit outlet includes a fitting.

The sublimation ampoule of any preceding clause, wherein the at least one chamber inlet includes a showerhead.

The sublimation ampoule of any preceding clause, wherein the at least one chamber inlet includes a fitting.

The sublimation ampoule of any preceding clause, wherein chambers adjacent to an outer wall of the sublimation container are heated at a greater temperature than a temperature of the chambers separated by the radial wall.

A sublimation ampoule comprising: a sublimation container having an open end and a closed end, a sidewall, and a central longitudinal axis, the sublimation container comprising: an interior wall extending across the sidewall of the sublimation container; a radial wall radial wall concentric with the central longitudinal; a first chamber and a second chamber separated by the interior wall; and, a third chamber and a fourth chamber and are separated from the first chamber and second chamber by the radial wall, and adjacent to the sidewall of the sublimation container; and, a container lid having a top surface and a bottom surface defining a thickness, the bottom surface removably securable to the open end of the sublimation container forming a fluid seal, the container lid comprising: a lid inlet positioned on the top surface of the container lid having a fixed inlet flow rate, the lid inlet extending through the thickness; at least one chamber inlet positioned on the bottom surface of the container lid fluidly connected to the lid inlet, the chamber inlet in fluid communication with the first chamber; the chamber inlet having a cross-sectional area; a lid outlet positioned on the top surface of the container lid having a fixed outlet pressure, the lid outlet extending through the thickness and in fluid communication with the fourth chamber; and, a plurality of conduits having a conduit inlet and a conduit outlet positioned on the bottom surface, the conduit inlet and conduit outlet extending partially into the thickness, the conduit fluidly connecting the first chamber, the second chamber, the third chamber and the fourth chamber, each of the plurality of conduits having cross-sectional area.

The sublimation ampoule of the preceding clause, wherein the first chamber is in fluid communication with the second chamber by at least one conduit of the plurality of conduits.

The sublimation ampoule of any preceding clause, wherein the third chamber and fourth chamber are in fluid communication by at least one conduit of the plurality of conduits.

The sublimation ampoule of any preceding clause, wherein the third chamber and the first chamber are in fluid communication by at least one conduit of the plurality of conduits.

The sublimation ampoule of any preceding clause, wherein the fourth chamber and the second chamber are in fluid communication by at least one conduit.

The sublimation ampoule of any preceding clause, father comprising heaters configured to heat the sidewall of the sublimation container.

The sublimation ampoule of any preceding clause, wherein the third chamber and fourth chamber are heated at a greater temperature than a temperature of first chamber and second chamber.

The sublimation ampoule of any preceding clause, wherein the sublimation rate of each chamber is defined by the surface area of each chamber, a temperature of each chamber, and the headspace pressure of each chamber, wherein the sublimation rate of each chamber is equal.

The sublimation ampoule of any preceding clause, wherein the sublimation rate of each chamber is equal.

The sublimation ampoule of any preceding clause, wherein the surface area of the first chamber is equal to the surface area of the second chamber, wherein the surface area of the third chamber is equal to the surface area of the second chamber.

The sublimation ampoule of any preceding clause, wherein the surface area of the first chamber and the second chamber are greater than the surface area of the third chamber and fourth chamber.

The sublimation ampoule of any preceding clause, wherein the headspace pressure of the first chamber is greater than the headspace pressures of each of the second chamber, the third chamber and the fourth chamber.

1. A sublimation ampoule comprising:
a sublimation container having an open end and a closed end, a sidewall and at least two chambers extending between the open end and the closed end, each chamber is separated by a container wall, each chamber having a surface area and a sublimation rate; and,
a container lid having a top surface and a bottom surface defining a thickness, the bottom surface removably securable to the open end of the sublimation container forming a fluid seal, the container lid comprising:
a lid inlet positioned on the top surface of the container lid, the lid inlet extending through the thickness;
a lid outlet positioned on the top surface of the container lid the lid outlet extending through the thickness;
at least one chamber inlet positioned on the bottom surface of the container lid fluidly connected to the lid inlet, each chamber inlet fluidly connected to a chamber of the at least two chambers, each chamber inlet having a cross-sectional area; and,
a conduit having a conduit inlet and a conduit outlet positioned on the bottom surface, the conduit inlet and conduit outlet extending partially into the thickness, the conduit fluidly connecting to two chambers of the at least two chambers, the conduit having cross-sectional area.

2. (canceled)

3. (canceled)

4. The sublimation ampoule of claim 1, further comprising heaters to facilitate heating of the sidewall of the sublimation container.

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. The sublimation ampoule of claim 1, wherein the closed end of the sublimation container is removably securable to the sidewall forming a fluid seal.

19. The sublimation ampoule of claim 1, further comprising an interior wall extending across the sidewall of the sublimation container, the interior wall separating the at least two chambers.

20. The sublimation ampoule of claim 1, further comprising a plurality of interior walls extending from a central longitudinal axis of the sublimation container to the sidewall of the sublimation container.

21. The sublimation ampoule of claim 1, further comprising a radial wall concentric with a central longitudinal axis of the sublimation container, the radial wall separating the at least two chambers.

22. (canceled)

23. The sublimation ampoule of claim 1, wherein the lid inlet is fluidly connected to a first chamber of the at least two chambers, and the lid outlet is fluidly connected to a second chamber of the at least two chambers.

24. The sublimation ampoule of claim 23, wherein a third chamber is fluidly connected to the first chamber by a second conduit, and the third chamber is fluidly connected to the second chamber by a third conduit, and the second chamber is fluidly connected to the lid outlet.

25. The sublimation ampoule of claim 2, wherein the lid inlet is fluidly connected to a second chamber inlet of the at least one chamber inlet defining a parallel connection of chambers.

26. The sublimation ampoule of claim 1, wherein the conduit includes a conduit inlet and at least two conduit outlets defining a parallel connection of chambers.

27. The sublimation ampoule of claim 1 further comprising at least one chamber outlet fluidly connected to the lid outlet, each chamber outlet fluidly connected to a chamber of the at least two chambers.

28. The sublimation ampoule of claim 1, wherein the sublimation container is subdivided into four chambers by an interior wall extending across the sidewall of the sublimation container and a radial wall concentric with a central longitudinal axis of the sublimation container.

29. The sublimation ampoule of claim 28, wherein a first chamber and a second chamber are separated by the interior wall, the first chamber in fluid communication with the lid inlet, the first chamber in fluid communication with the second chamber by at least one conduit.

30. The sublimation ampoule of claim 29, wherein a third chamber and a fourth chamber are adjacent to the sidewall of the sublimation container and are separated from the first chamber and second chamber by the radial wall, and the third chamber and forth chamber are separated by the interior wall, the fourth chamber in fluid communication with the lid outlet.

31. (canceled)

32. (canceled)

33. (canceled)

34. (canceled)

35. The sublimation ampoule of claim 1, wherein the cross-sectional area of the conduit is less than the cross-sectional area of the lid inlet.

36. The sublimation ampoule of claim 1, wherein at least two conduits fluidly connect two chambers of the at least two chambers.

37. The sublimation ampoule of claim 1, wherein the conduit outlet includes a showerhead.

38. (canceled)

39. The sublimation ampoule of claim 1, wherein the at least one chamber inlet includes a showerhead.

40. (canceled)

41. (canceled)

42. A sublimation ampoule comprising:
a sublimation container having an open end and a closed end, a sidewall, and a central longitudinal axis, the sublimation container comprising:
an interior wall extending across the sidewall of the sublimation container;
a radial wall radial wall concentric with the central longitudinal;
a first chamber and a second chamber separated by the interior wall; and,
a third chamber and a fourth chamber and are separated from the first chamber and second chamber by the radial wall, and adjacent to the sidewall of the sublimation container; and,
a container lid having a top surface and a bottom surface defining a thickness, the bottom surface removably securable to the open end of the sublimation container forming a fluid seal, the container lid comprising:
a lid inlet positioned on the top surface of the container lid having a fixed inlet flow rate, the lid inlet extending through the thickness;
at least one chamber inlet positioned on the bottom surface of the container lid fluidly connected to the lid inlet, the chamber inlet in fluid communication with the first chamber; the chamber inlet having a cross-sectional area;
a lid outlet positioned on the top surface of the container lid having a fixed outlet pressure, the lid outlet extending through the thickness and in fluid communication with the fourth chamber; and,
a plurality of conduits having a conduit inlet and a conduit outlet positioned on the bottom surface, the conduit inlet and conduit outlet extending partially into the thickness, the conduit fluidly connecting the first chamber, the second chamber, the third chamber and the fourth chamber, each of the plurality of conduits having cross-sectional area.

43. The sublimation ampoule of claim 42, wherein the first chamber is in fluid communication with the second chamber by at least one conduit of the plurality of conduits.

44. The sublimation ampoule of claim 42, wherein the third chamber and fourth chamber are in fluid communication by at least one conduit of the plurality of conduits.

45. The sublimation ampoule of claim 42, wherein the third chamber and the first chamber are in fluid communication by at least one conduit of the plurality of conduits.

46. The sublimation ampoule of claim 42, wherein the fourth chamber and the second chamber are in fluid communication by at least one conduit.

47. The sublimation ampoule of claim 42, father comprising heaters configured to heat the sidewall of the sublimation container.

48. (canceled)

49. (canceled)

50. (canceled)

51. (canceled)

52. (canceled)

53. (canceled)
